(19) United States
(12) Patent Application Publication
(10) Pub. No.: US 2005/0034046 A1
(43) Pub. Date: Feb. 10, 2005

(54) Combined interleaver and deinterleaver, and turbo decoder comprising a combined interleaver and deinterleaver

(75) Inventors: Jens Berkmann, Munchen (DE); Thomas Herndl, Biedermannsdorf (AT)

Correspondence Address: Andreas Grubert;Baker Botts L.L.P., One Shell Plaza, 910 Louisiana, Houston, TX, 77002-4995, US

(73) Assignee: Infineon Technologies AG

(21) Appl. No.: 10/920,902

(22) Filed: Aug. 18, 2004

Related U.S. Application Data
(63) Continuation of application No. PCT/DE03/00145, filed on Jan. 20, 2003.

(30) Foreign Application Priority Data
Feb. 18, 2002 (DE) 102 06 727.9

(51) Int. Cl. H03M 13/00

(52) U.S. Cl. 714/755

(57) ABSTRACT

A combined interleaving and deinterleaving circuit (IDL1) has a first data memory (RAM) for temporary storage of the data to be interleaved and deinterleaved. A first address generator produces a sequence of sequential addresses, and a second address generator (AG) produces a sequence of addresses which represents the interleaving rule (α(i)). A logic means (XOR, MUX) causes the data memory (RAM) to be addressed by the second address generator (AG) in the interleaving mode for a read process and in the deinterleaving mode for a write process.

### CROSS REFERENCE APPLICATION

This application is a continuation of copending International Application No. PCT/DE03/00145 filed Jan. 20, 2003 which designates the United States, and claims priority to German application no. 102 06 727.9 filed Feb. 18, 2002.

### TECHNICAL FIELD OF THE INVENTION

The invention relates to circuits which carry out interleaving or deinterleaving of a data stream as a function of a selected mode, and to turbo-decoders which have a circuit such as this. The invention also relates to methods for carrying out interleaving and deinterleaving procedures, as well as methods for turbo-decoding of a data stream which has been channel-coded using a turbo-code.

### BACKGROUND OF THE INVENTION

In communications systems, for example mobile radio systems, the signal to be transmitted is subjected to channel coding and interleaving after being preprocessed in a source coder. Both measures provide the signal to be transmitted with a certain amount of robustness. In the case of channel coding, effective error protection is created by deliberately introducing redundancy into the signal to be transmitted. The interleaving results in channel disturbances which would result in group bit errors (so-called group errors) without interleaving affect data which is distributed in time in the signal to be transmitted, thus causing individual bit errors which can be tolerated better.

The interleaving (which is carried out in the transmitter) of the data stream to be transmitted is carried out in the form of data blocks, that is to say the data bits in each block are permutated by the transmitter-end interleaver using the same interleaving rule. The reverse transformation, by means of which the data bits are changed back to their original sequence, is carried out in the receiver by means of a deinterleaver using the inverse deinterleaving rule.

Binary, recursive convolutional codes which are linked in parallel are referred to as so-called turbo-codes. Turbo-coding combines the addition of redundancy to the interleaving of the data stream to be transmitted. Particularly when large data blocks are being transmitted, turbo-codes represent a powerful form of error protection coding.

The UMTS (Universal Mobile Telecommunications System-) Standard provides for the use of a turbo-code for channel coding. The interleaving and deinterleaving rules are specified in the UMTS Standard as a function of the (variable) block length, which is between 40 and 5114 bits. The calculation of the interleaving rule (that is to say of the addresses for the permutation of the bits of the data block) is specified in Sections 4.2.3.2.3.1. to 4.2.3.2.3.3. of the Technical Specification 3GPP TS 25.212 V3.5.0 (2000-12).

The document U.S. Pat. No. 5,659,850 describes an interleaver which carries out the interleaving rule as defined in the IS95 Standard. The interleaver has a data memory for storage of the data to be interleaved, a continuous address counter, and an address interchanger. The continuous address counter produces the addresses for loading of the data memory, while the address interchanger produces the addresses for reading the data memory in accordance with the specified interleaving rule.

Conventional deinterleavers generally have the same structural configuration as an interleaver. Deinterleaving is carried out by reading the data from the data memory using the inverse deinterleaving rule.

Both interleavers and deinterleavers are required in some circuits. One very important representative of a circuit type such as this is a turbo-decoder, which is used in radio receivers to once again remove the redundancy, which was added during the turbo-coding process, from the received data stream.

Decoding of a turbo-coded data stream requires a relatively large amount of computation effort. The high degree of computation effort is a result on the one hand of the fact that turbo-decoding is based on the use of an iterative method in which the individual data items must be decoded repeatedly as a consequence of repeatedly passing through a recursion loop. Furthermore, as a consequence of the inherent interleaving procedure for the production of the turbo-code, an interleaving procedure and a deinterleaving procedure must in each case be carried out in each iteration loop.

Conventional turbo-decoders thus contain an interleaver and a deinterleaver. The interleaver and the deinterleaver are implemented independently of one another, that is to say both the interleaver and the deinterleaver are allocated a RAM area whose size is K*Q, where K is the block length and Q is the word length of the data to be interleaved and deinterleaved (so-called soft bits). The interleaver in this case operates on the basis of the interleaving rule, and the deinterleaver operates on the basis of the (inverse) deinterleaving rule.

In the event of a change to the block length K or during initialization of the turbo-decoder in the course of a system start, the interleaving rule must first of all be calculated in accordance with the UMTS Specifications. This rule is defined in the UMTS Standard in the form of a coordinate transformation matrix. The deinterleaving rule relating to the rule is then obtained by inversion of the coordinate transformation matrix.

### SUMMARY OF THE INVENTION

The invention is based on the object of specifying a circuit which allows both interleaving and deinterleaving to be carried out, and which involves a low level of implementation complexity. A further aim of the invention is to specify an interleaving and deinterleaving method which can be carried out with little effort. One particular aim of the circuit according to the invention and of the method according to the invention is to reduce the implementation complexity for use in a turbo-decoder.

A first circuit type comprises a data memory for temporary storage of the data in a data stream. The circuit furthermore comprises a first address generator, which produces a sequence of sequential addresses for addressing the data memory, and a second address generator, which produces a sequence of addresses which represents the interleaving rule for addressing the data memory. A logic means causes the data memory to be addressed by the second address generator in the interleaving mode for a read process and in the deinterleaving mode for a write process, and to be addressed by the first address generator in the interleaving mode for a write process, and in the deinterleaving mode for a read process.

The combined interleaving and deinterleaving circuit according to the invention has the advantage that it requires only one memory area for carrying out the two operating modes (interleaving/deinterleaving). A further significant advantage is that the same address sequence (which is produced by the second address generator) is used both for the interleaving process and for the deinterleaving process. There is no need to convert this “interleaving address sequence” to the corresponding “deinterleaving address sequence”.

The circuit according to the second aspect of the invention corresponds structurally to the circuit described above, but the function of the second logic means differs from the function of the first logic means. The major difference is that, for the loading of the data memory in the course of an interleaving procedure for the circuit according to the second aspect of the invention, the address sequence is used by the second address generator and this must in consequence be available at this stage, while this is not necessary for the circuit according to the first aspect of the invention. Otherwise, the circuit according to the second aspect of the invention likewise has the advantages already mentioned.

In principle, the first address generator, the second address generator as well as the first and/or second logic means may be either in the form of hardware or in the form of software. “In the form of software” means that a program is carried out in machine code in order to calculate the respective results (address sequences and logic values). In contrast to this, a hardware implementation comprises logic and arithmetic elements which do not process machine code. One particularly advantageous refinement of the circuits according to the invention is characterized in that the first and/or second logic means comprises an XOR gate, whose inputs are connected to the write/read signal for the data memory and to a mode signal which indicates the mode. Furthermore, it contains a multiplexer, whose control input is connected to the output of the XOR gate, and whose multiplexer inputs are connected to the first and to the second address generator. This results in a simple hardware implementation of the logic means.

The invention also relates to a turbo-decoder which comprises a channel decoder and a circuit for interleaving and deinterleaving a data stream. This circuit allows the interleaving and deinterleaving procedures which have to be carried out in the course of turbo-decoding to be carried out with only one common data memory and without calculation of inverse interleaving and deinterleaving rules.

One particularly advantageous embodiment of the turbo-decoder according to the invention is characterized in that this turbo-decoder comprises a circuit for interleaving and deinterleaving a data stream. The reason why a turbo-decoder having a circuit for interleaving and deinterleaving has specific advantages over turbo-decoder having a circuit for interleaving and deinterleaving is that, on the one hand, the calculation of the interleaving addresses for the UMTS Standard is associated with a relatively high degree of computational complexity and, on the other hand, the interleaving procedure during the first run through the turbo-decoding loop takes place at a time before the deinterleaving procedure. These characteristics make it possible to carry out the initialization of the interleaving step (that is to say the address calculation in the second address generator) in parallel with the first decoding process, thus making it possible to achieve a considerable time saving (the channel decoder does not have to wait for completion of the address calculation in the second address generator). A further advantage of this embodiment is that the algorithm for calculation of the interleaving addresses is specified in the UMTS Standard, so that they can be calculated in a known manner (although admittedly involving a large amount of computation effort). In contrast, direct calculation of the deinterleaving addresses (without previous calculation of the interleaving addresses) for the UMTS Standard would be associated with further considerations and difficulties.

A further advantageous refinement of the turbo-decoder according to the invention is characterized in that the turbo-decoder is designed to carry out decoding on the basis of the sliding window technique and comprises, as available rewriteable memory area, only the common data memory in the circuit for interleaving and deinterleaving, and a buffer store for temporary storage of interleaved and deinterleaved data which has been read from the data memory, whose memory size is matched to the length of the sliding window. Since the memory size of the buffer store can be designed to be considerably smaller than the memory size of the common data memory of the circuit for interleaving and deinterleaving, this results in the total memory requirement being virtually halved in comparison to conventional solutions, which each have separate memory areas for the interleaver and the deinterleaver.

### BRIEF DESCRIPTION OF THE DRAWING

The invention will be explained in the following text using exemplary embodiments and with reference to the drawing, in which:

FIG. 1 shows an outline illustration of an interleaver;

FIG. 2 shows a first architecture of an interleaver;

FIG. 3 shows a second architecture of an interleaver;

FIG. 4 shows an outline illustration of a deinterleaver;

FIG. 5 shows a first architecture of a deinterleaver;

FIG. 6 shows a second architecture of a deinterleaver;

FIG. 7 shows a first exemplary embodiment of a combined interleaver and deinterleaver according to the invention;

FIG. 8 shows a second exemplary embodiment of a combined interleaver and deinterleaver according to the invention;

FIG. 9 shows a block diagram of a known turbo-coder for production of a turbo-code;

FIG. 10 shows a block diagram of a known turbo-decoder for decoding of a turbo-coded data stream;

FIG. 11 shows an illustration of an architecture of a turbo-decoder according to the invention with an internal combined interleaver and deinterleaver;

FIG. 12 shows a timing diagram for the architecture illustrated in FIG. 11, in order to explain the sliding window technique when using a buffer store; and

FIG. 13 shows a timing diagram for the architecture illustrated in FIG. 11, in order to explain the sliding window technique when using two buffer stores.

### DESCRIPTION OF THE INVENTION

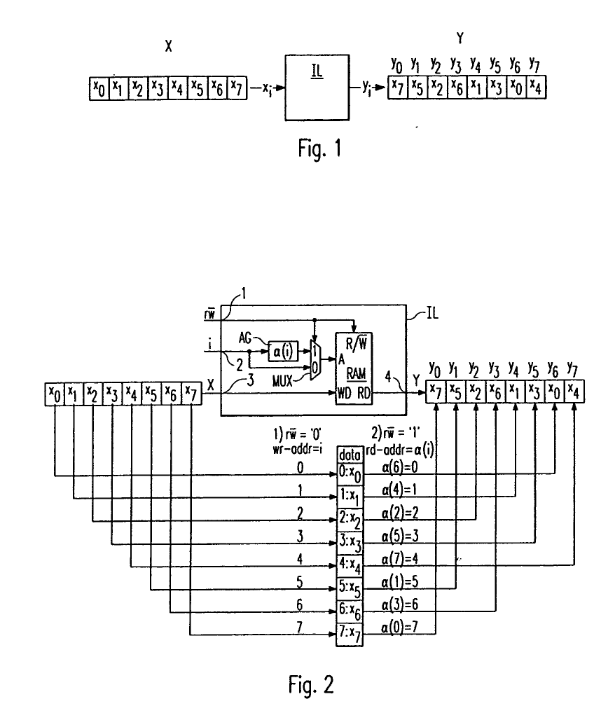

FIG. 1 illustrates the general principle of interleaving. An interleaver IL receives a non-interleaved data sequence X={X₀,X₁,X₂, . . . ,Xₖ₋₁}, reorganizes the individual data items Xᵢ, i=0.1, . . . ,K-1, and emits an interleaved data sequence Y={Y₀,Y₁,Y₂, . . . ,Yₖ₋₁}. K denotes the sequence length on which the interleaving process is based, and which is also referred to in the following text as the block length. Since the interleaving is carried out in blocks, the interleaver IL is also referred to as a block interleaver. FIG. 1 shows one example, for K=8. This clearly shows that the interleaving is a reorganization of the time sequence of the data in the input data sequence X. The rule on the basis of which the reorganization is carried out can be read directly on the interleaved data sequence Y.

This rule can be expressed as a function α(i), where α(i) indicates the time step index in the input data stream from which a data item x_{α}(i) which is to be positioned at the time step index i in the output data stream should be related. This means that the rule α(i) is as follows:

“Map the data item in the input data stream for the time step index α(i) onto the time step index i in the output data stream: x_{α(i)}=>yᵢ”

FIG. 2 shows an implementation example of the interleaver IL from FIG. 1. The interleaver IL comprises a data memory RAM, a two-way multiplexer MUX and an address generator AG, which implements the interleaving rule α(i).

The interleaver IL has a first input 1 to which a read/write signal r\overline{w} is applied. A second input 2 receives an address signal i, which corresponds to the time step index i in the input data sequence X, and can be produced, for example, by a counter. The input data sequence, X is applied to a third input 3.

The read/write signal r\overline{w} is passed to the read/write switching R/\overline{W} in the data memory RAM and, furthermore, to the control input of the multiplexer MUX. It can assume the values r\overline{w}=0 (write) and r\overline{w}=1 (read). The address signal i is applied to the input of the address generator AG and to that input of the multiplexer MUX which is associated with the value r\overline{w}=0. The output signal from the address generator AG is passed to the other input (r\overline{w}=1) of the multiplexer MUX. The output of the multiplexer MUX is connected to an address input A of the data memory RAM.

The data memory RAM also has a write data input WD and a read data input RD. The write data input WD is supplied with the data sequence X which is received via the input 3, and the write data output RD emits the interleaved data sequence Y via an output 4 of the interleaver IL.

The lower part of FIG. 2 shows the method of operation of the interleaver IL:

In a first step, the data sequence X of length K is written to the data memory RAM (r\overline{w}=0; i=0,1,2 . . . ,K-1). The write addressing which is applied to the address input A corresponds directly to the input time step index i.

In a second step, data is read from the data memory RAM (r\overline{w}=1, i=0,1,2, . . . ,K-1), with the function α(i) being used for addressing of the data memory RAM. α(i) indicates that address in the data memory RAM from which a data item is intended to be taken and is intended to be emitted for the output time step index i.

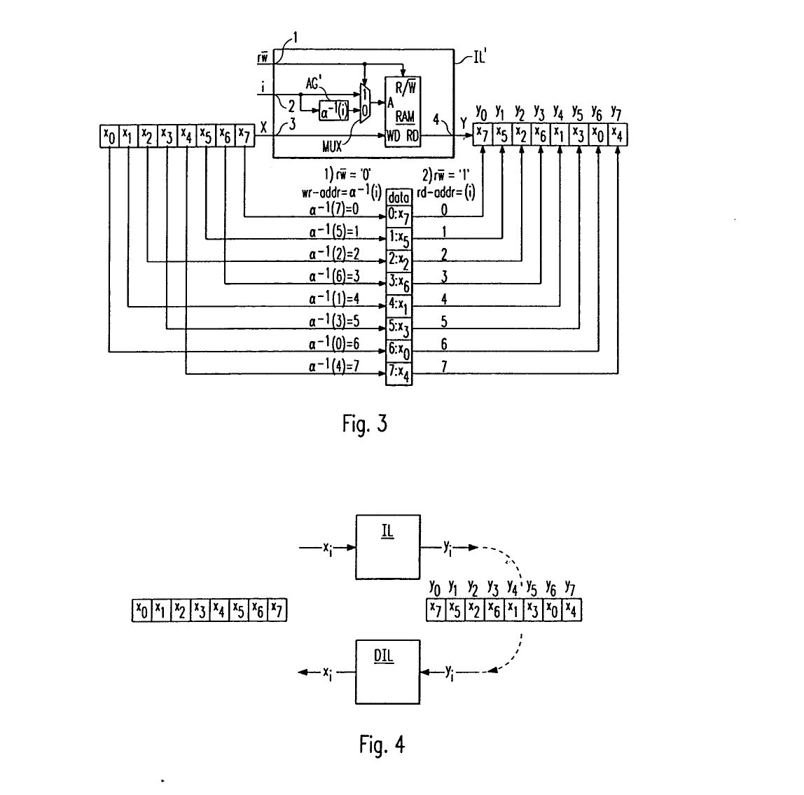

The addressing process, which has been explained in FIG. 2, is referred to as being non-interleaved, since it is oriented on the time step index of the non-interleaved data sequence X. FIG. 3 illustrates an alternative architecture for an interleaver IL′. This architecture differs from the arrangement illustrated in FIG. 2 in that an address generator AG′, which carries out the inverse function α⁻¹(i), is connected to that input of the multiplexer MUX which is associated with the value r\overline{w}=0. The expression “interleaved internal addressing” is used in this case, since this is oriented on the time step index of the interleaved data sequence Y. This means that the address generation process is carried out by the address generator AG′ for the write process (r\overline{w}=0) and not for the read process r\overline{w}=1 (as in the case of the interleaver IL shown in FIG. 2).

In FIGS. 2 and 3, wr-addr denotes the write addresses and rd-addr denotes the read addresses for memory addressing. For the architecture illustrated in FIG. 2, wr-addr=i (write process) and rd-addr=α(i) (read process). For the architecture illustrated in FIG. 3, wr-addr=α⁻¹(i) (write process) and rd-addr=i (read process).

With regard to the logical input/output behaviour, the two interleavers IL and IL′ are identical.

FIG. 4 shows the principle of a deinterleaver DIL. On the input side, the deinterleaver DIL receives the interleaved data sequence Y and, on the output side, emits the original, deinterleaved data sequence X. In other words, the deinterleaver DIL once again reverses the reorganization of the data stream that was carried out by the interleaver IL, IL′.

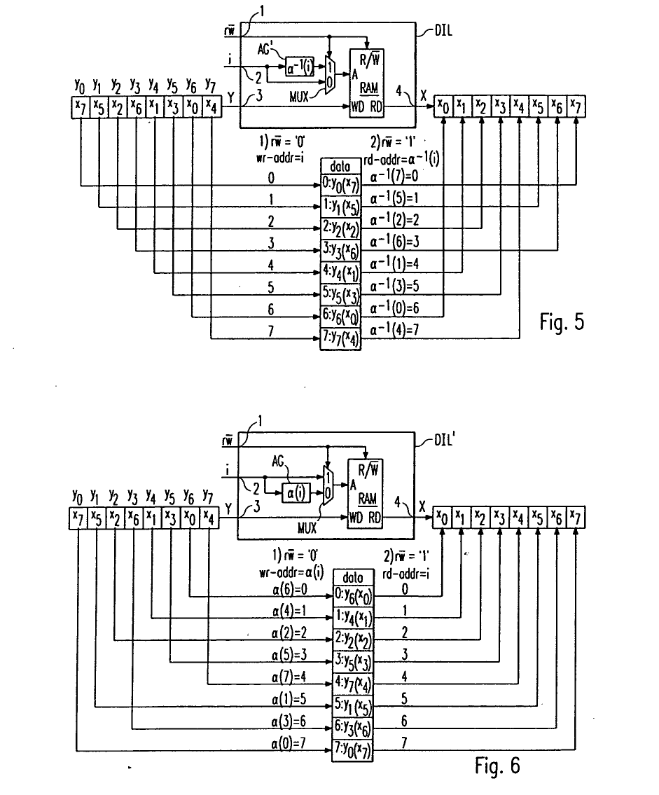

Since deinterleaving is the inverse process to interleaving, the deinterleaver DIL (see FIG. 5) can be configured on the basis of the architecture of the interleaver IL as illustrated in FIG. 2. The only difference is that the inverse address function α⁻¹(i) must be carried out instead of α(i) when reading the data. The deinterleaver DIL′ as illustrated in FIG. 6 is formed analogously to this on the basis of the architecture of the interleaver IL′ as illustrated in FIG. 3. The function α(i) is used here instead of the function α⁻¹(i) for writing the data. The deinterleavers DIL and DIL′ are equivalent in terms of their logical input/output behaviour (although they are not functionally equivalent).

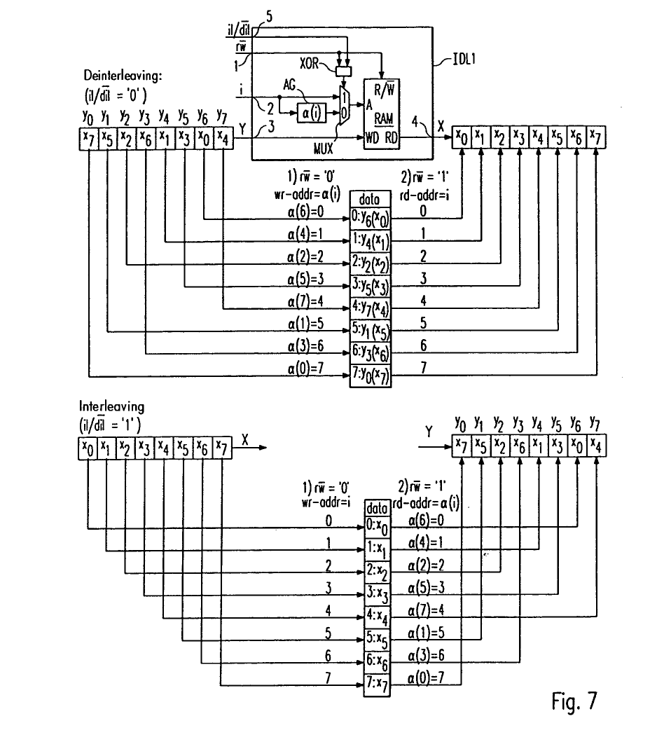

FIG. 7 shows a first exemplary embodiment of a combined interleaver and deinterleaver IDL1 according to the invention. The same functional elements are annotated by the same reference symbols as in the previous figures. The interleaver and deinterleaver IDL1 according to the invention differs from the interleaver IL shown in FIG. 2 first of all by having a further input 5 and an XOR gate XOR. The input 5 is connected to one input of the XOR gate XOR, and the other input of the XOR gate XOR is connected to the input 1. The output of the XOR gate XOR controls the multiplexer MUX. Furthermore, a further difference is that the multiplexer inputs are interchanged in comparison to the interleaver IL illustrated in FIG. 2, that is to say the address generator AG is connected to the multiplexer input “0”, and the index counter (not illustrated) is connected to the multiplexer input “1”.

A mode signal il/\overline{dil} is applied via the input 5 and indicates whether interleaving (il/\overline{dil}=1) or deinterleaving (il/\overline{dil}=0) should be carried out. This mode signal il/\overline{dil} in conjunction with the logic of the XOR gate results in the combined interleaver and deinterleaver IDL1 operating in the interleaving mode, corresponding to the interleaver IL as illustrated in FIG. 2 (see FIG. 7, lower part) and operating in the deinterleaving mode in a corresponding manner to the deinterleaver DIL′ illustrated in FIG. 6 (see FIG. 7, upper part). In other words, the combined interleaver and deinterleaver IDL1 carries out a non-interleaved addressing process, which is oriented on the sequence X, with the address generator AG in both modes il/\overline{dil}=0,1. Only the one (address mapping) function α(i) is thus required in the combined interleaver and deinterleaver IDL1. Furthermore, the same memory area RAM is used for both operating modes.

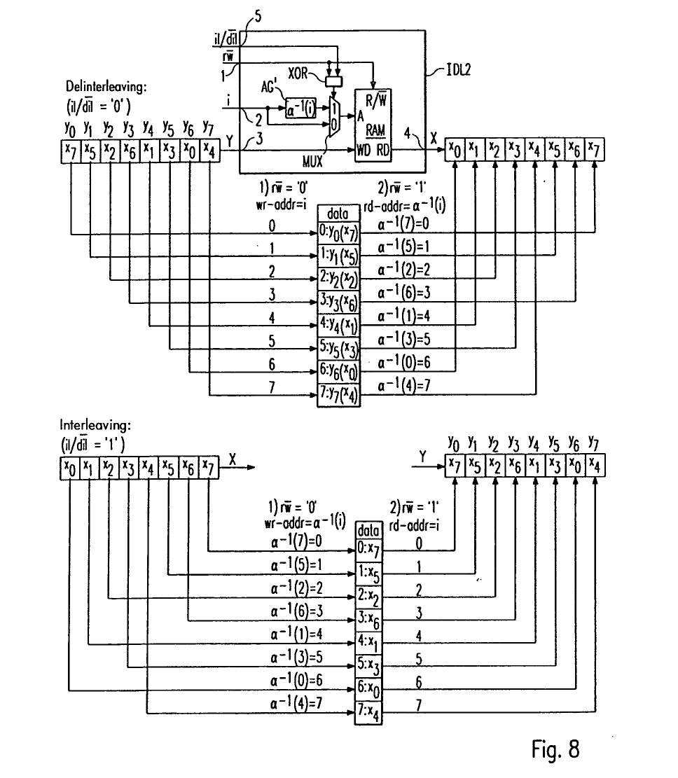

A second exemplary embodiment of a combined interleaver and deinterleaver IDL2 according to the invention is illustrated in FIG. 8. Its structure corresponds to the configuration of the combined interleaver and deinterleaver IDL1 as shown in FIG. 7, but with the address generator AG′ with the mapping function α⁻¹(i) being used instead of the address generator AG with the mapping function α(i), and with the inputs of the multiplexer MUX being interchanged. The interleaver and deinterleaver IDL2 which is illustrated in FIG. 8 carries out interleaved addressing, which is linked to the sequence Y in both modes.

The two combined interleavers and deinterleavers IDL1 and IDL2 have the common feature that (except for the additional input 5 and the XOR gate XOR) their complexity is equivalent only to that of a single interleaver (or deinterleaver). Furthermore, they have the same logical input/output behaviour. Both IDL1 and IDL2 require only a single-ported memory area RAM.

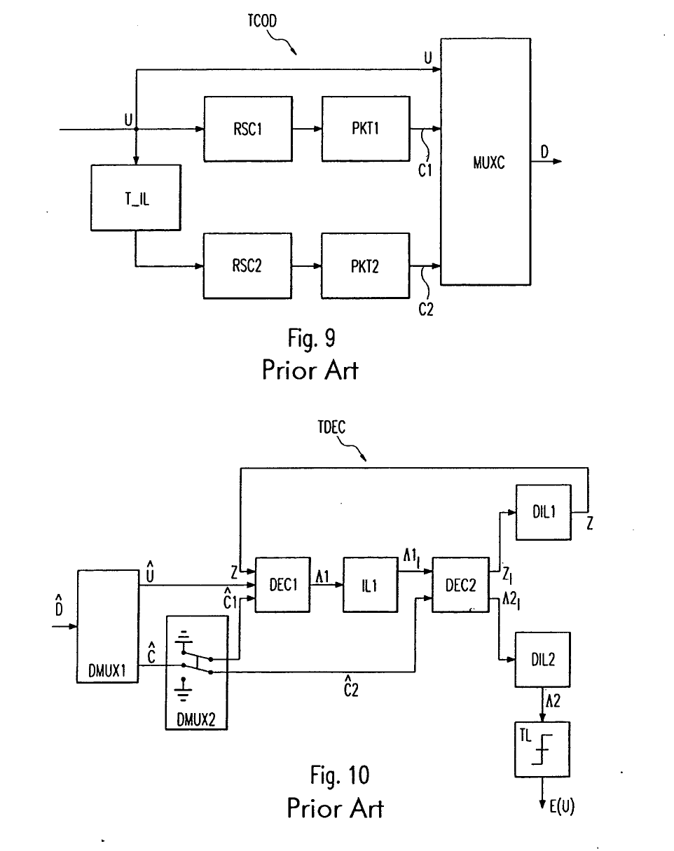

In order to assist understanding of a turbo-decoder, the known design of a turbo-coder TCOD will first of all be explained, by way of example, with reference to FIG. 9.

The turbo-coder TCOD illustrated here has a turbo-interleaver T_IL, two identical, recursive, systematic convolutional coders RSC1 and RSC2 (for example 8-state convolutional coders), two optional puncturing means PKT1 and PKT2, and a multiplexer MUXC. The input signal is a bit sequence U which is to be coded and which may, for example, be a source-coded speech or video signal.

The turbo-coder TCOD produces a digital output signal D, which is produced by multiplexing of the input signal U (so-called systematic signal), of a signal C1 which has been coded by means of RSC1 and may have been punctured by PKT1, and of a signal C2 which has been interleaved by T_IL, has been coded by RSC2, and may have been punctured by PKT2.

In the UMTS Standard, the block length K is variable, and is between 40 and 5114 bits. A specific interleaving rule is specified for each data block length K in the Standard, and the turbo-interleaver T_IL operates on the basis of this rule.

The error-protection-coded data signal D is then modulated in some suitable manner onto a carrier, and is transmitted via a transmission channel.

The decoding of a turbo-coded received signal in a receiver will be explained in the following text with reference to the known turbo-decoder TDEC, which is illustrated in FIG. 10.

The turbo-decoder TDEC comprises a first and a second demultiplexer DMUX1 and DMUX2, a first and a second convolutional decoder DEC1 and DEC2, a turbo-interleaver IL1, a first and a second turbo-deinterleaver DIL1 and DIL2, as well as decision logic (threshold value decision maker) TL.

A demodulator (which is not illustrated) in the receiver produces an equalized data sequence \hat{D}, which is the coded data sequence D as reconstructed in the receiver.

The method for operation of the turbo-decoder TDEC which is illustrated in FIG. 10 will be explained briefly in the following text.

The first demultiplexer DMUX1 splits the equalized data signal \hat{D} into the equalized systematic data signal Û (reconstructed version of the input signal U) and an equalized redundant signal Ĉ. The latter is split by the second demultiplexer DMUX2 (as a function of the multiplexing and puncturing rule that is used in the turbo-coder TCOD) into the two equalized redundant signal elements Ĉ1 and Ĉ2 (which are the reconstructed versions of the redundant signal elements C1 and C2).

The two convolutional decoders DEC1 and DEC2 may, for example, be MAP symbol estimators. The first convolutional decoder DEC1 uses the data signals Û and Ĉ1 and a feedback signal Z (so-called extrinsic information) to calculate first logarithmic reliability data Λ1 in the form of LLRs (log likelihood ratios).

The first reliability data Λ1, which also includes the systematic data in the data signal Û is interleaved by the turbo-interleaver IL1, and the interleaved reliability data Λ1_{I} is supplied to the second convolutional decoder DEC2. The methods of operation of the turbo-interleavers T_IL and IL1 are identical (but T_IL interleaves a bit stream and IL1 interleaves a data stream with word lengths of more than 1). The second convolutional decoder DEC2 uses the interleaved reliability data Λ1_{I} and the reconstructed redundant signal element data Ĉ2 to calculate an interleaved feedback signal Z_{I} and interleaved second logarithmic reliability data Λ2_{I}, likewise in the form of LLRs.

The interleaved feedback signal Z_{I} is deinterleaved by the first turbo-deinterleaver DIL1, and results in the feedback signal Z.

The illustrated recursion loop is passed through repeatedly. Each pass is based on the data from the same data block. Two decoding steps are carried out (in DEC1 and DEC2) in each pass. The interleaved second reliability data Λ2_{I} which is obtained from the final pass is deinterleaved by the second deinterleaver DIL2, and is passed as deinterleaved reliability data Λ2 to the decision logic TL.

The decision logic TL then determines a binary data signal E(U), which is a sequence of estimated values for the bits in the input signal U.

After the turbo-decoding of a data block and the emission of the appropriate sequence of estimated values E(U), the next data block is turbo-decoded.

As is evident from the turbo-decoder TDEC illustrated by way of example in FIG. 10, turbo-decoding comprises a turbo-interleaving procedure (IL1) and a turbo-deinterleaving procedure (DIL1) in each pass through the loop. Two autonomous circuits (interleaver and deinterleaver) are used for this purpose in the conventional implementation of a turbo-decoder. Furthermore, two data memories, whose size corresponds to that of a data block, are used, and generators are required to produce the interleaving rule and the inverted interleaving rule.

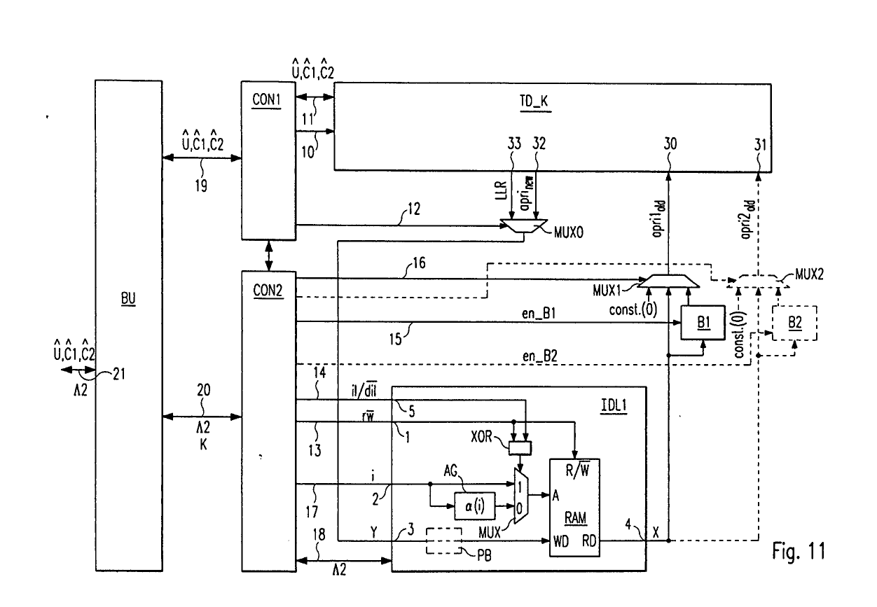

FIG. 11 shows the architecture of one exemplary embodiment of a turbo-decoder according to the invention (the signal splitting on the input side in FIG. 10 is achieved by means of the demultiplexers DMUX1 and DMUX2 in FIG. 11).

The circuit comprises a turbo-decoder core TD_K, which carries out the convolutional decoding, and thus carries out the tasks of the two circuit blocks DEC1 and DEC2 in FIG. 10. The turbo-decoder core TD_K is connected to a first control unit CON1, which, via a control connection 10, carries out sequence control for the turbo-decoder core TD_K, and allows data to be interchanged via a bidirectional data link 11 (in particular the data sequences (Û, Ĉ1, Ĉ2).

Furthermore, the circuit comprises a second control unit CON2, two multiplexers MUX0 and MUX1, the combined interleaver and deinterleaver IDL1 and a buffer store B1.

The first control unit CON1 is connected via a control connection 12 to the control input of the first multiplexer MUX0. The inputs of the multiplexer MUX0 are fed from two outputs 32 and 33 of the turbo-decoder core TD_K. The first output 32 emits the first (non-interleaved) reliability data Λ1 and the (interleaved) extrinsic information Z_{I}. Since both Λ1 and Z_{I} always form input information for a subsequent decoding process, they are both referred to in the following text as (new) a priori information, in accordance with the normal terminology. The second output 33 emits the second (interleaved) reliability data Λ2_{I}. In the following text, this is referred to as (interleaved) LLRs.

The second control unit CON2 monitors and controls the combined interleaver and deinterleaver IDL1, the second multiplexer MUX1 and the buffer store B1. For this purpose, it is connected via control connections 13 (read-write switching) and 14 (mode signal) to the inputs 1 and 5 of the combined interleaver and deinterleaver IDL1. A signal en_B1 can be applied via a control connection 15 in order to activate the buffer store B1, while a control connection 16 is passed to the control input of the second multiplexer MUX1.

A data link 17 which runs between the second control unit CON2 and the combined interleaver and deinterleaver IDL1 feeds the address input 2 of the combined interleaver and deinterleaver IDL1.

Bidirectional data interchange is possible between the second control unit CON2 and the combined interleaver and deinterleaver IDL1 via a data link 18. The two control units CON1 and CON2 are linked to a bus structure BU via bidirectional data links 19 and 20. The bus structure BU interchanges data via a bidirectional data link 21 with a processor (not illustrated).

It should be mentioned that the combined interleaver and deinterleaver IDL1 may also have a small buffer PB (pipeline buffer, shown by dashed lines) between the input 3 and the write data input WD, which compensates for pipeline delays during pipeline processing. In this case, its size corresponds to the number of pipeline stages.

The architecture illustrated in FIG. 11 is used for iterative turbo-decoding using the sliding window technique. The sliding window technique as such is known and, for example, is described in German Patent Application DE 100 01 856 A1 and in the article “Saving memory in turbo-decoders using the Max-Log-MAP algorithm” by F. Raouafi, et al., IEE (Institution of Electrical Engineers), pages 14/1-14/4. These two documents are in this context included by reference in the disclosure content of the present application.

The sliding window technique is based on the following: during the symbol estimation process in the turbo-decoder core TD_K, a forward recursion process and a backward recursion process must be carried out in order to calculate the a priori information and the LLRs. At least the result data obtained from the forward recursion process must be buffer-stored, in order to allow it to be combined later with the resulting data obtained from the backward recursion process to form the priori information (and the LLRs). If the sliding window technique were not used, both recursion processes would have to be carried out over the entire block length K. In consequence, a memory requirement corresponding to K*Q is required, where Q denotes the word length of the data to be stored.

The sliding window technique comprises the recursion runs being carried out segment-by-segment within a specific window. The position of the window is in this case shifted in steps over the entire block length K.

With the sliding window technique, the size of the buffer store B1 need be only WS*Q, where WS denotes the length of the overlap area of the forward and backward recursion processes (which is normally identical to the length of the forward recursion process). Particularly in the case of large data blocks, WS may be chosen to be several orders of magnitude less than K.

The method of operation of the architecture as illustrated in FIG. 11 will be explained in the following text:

First of all, the processor (not illustrated) transfers all the required parameters and data via the bus structure BU to the control units CON1 and CON2. For the turbo-decoder core TD_K, this includes, inter alia, the input data Û, Ĉ1, Ĉ2. The combined interleaver and deinterleaver IDL1 must be able to use suitable information to carry out the interleaving and deinterleaving processes envisaged for the block length K. For this purpose, it is either possible to calculate the function α(i) in the processor and to transfer this to the address generator AG (in this case, the address generator AG is in the form of a table memory), or only parameters (in the extreme only the block length K) on whose basis the address generator AG calculates the function α(i) automatically in hardware are signalled to the address generator AG.

The turbo-decoder core TD_K does not wait for the initialization of the combined interleaver and deinterleaver IDL1, but immediately starts to decode the input data. The first computation run of the turbo-decoder core TD_K and the initialization of the combined interleaver and deinterleaver IDL1 thus take place at the same time. This simultaneous operation is possible since the “old” a priori information (that is to say the extrinsic information Z (see FIG. 10)) which is supplied to the turbo-decoder core TD_K via an input 30 from the second multiplexer MUX1 is constant in the first iteration loop (no information is available), and since the new a priori information produced by the turbo-decoder core TD_K can be written directly to the data memory RAM for the combined interleaver and deinterleaver IDL1. The latter is possible because the address calculation which is based on the function α(i) is not required for writing the data to the single-port data memory RAM (see FIG. 7).

It should be mentioned that this advantage is not achieved if the interleaver and deinterleaver IDL2 is used instead of the interleaver and deinterleaver IDL1.

The first computation run of the turbo-decoder score TD_K is ended and the initialization of the combined interleaver and deinterleaver IDL1 is completed at a specific time.

The second computation run now starts (and corresponds to the calculation by DEC2 in FIG. 10). The turbo-decoder core TD_K for this purpose requires interleaved (old) a priori information (Λ1_{I}), which is supplied to the turbo-decoder core TD_K via the input 30, via the output 4 of the combined interleaver and deinterleaver ILD1 and the second multiplexer MUX1. (The combined interleaver and deinterleaver IDL1 is for this purpose driven via the signal lines 13 and 14 where r\overline{w}=1 and il/\overline{dil}=1.) The calculation of new interleaved a priori information (this being the interleaved extrinsic information Z_{I}) is now carried out on the basis of “regular” processing which can be subdivided into four steps when using the sliding window technique:
1. The forward metrics for WS time steps are calculated; to do this, the turbo-decoder core TD_K requires WS items of interleaved a priori information, which is produced at the output 4 of the combined interleaver and deinterleaver IDL1 by means of α(i), i=0, . . . ,WS-1. These WS values are, furthermore, temporarily stored in the buffer store B1 for further use.
2. The backward metrics for X time steps are then calculated (X is dependent on the specifically selected turbo-decoder algorithm). For this purpose, the turbo-decoder core TD_K requires X interleaved a priori information items, which are read by means of α(i), i=X−1, . . . , WS via the output 4 from the combined interleaver and deinterleaver IDL1. The interleaved a priori information between i=WS-1, . . . , 0 which is likewise required is obtained from the buffer store B1 (appropriate switching of the multiplexer MUX1 via the control connection 16 is carried out for this purpose).
3. The new a priori information is then calculated “on-the-fly” in the area of the overlapping section of the forward and backward recursion processes. In the course of this calculation, the old a priori information is read from the buffer store B1, and the turbo-decoder core TD_K generates (with a certain processing latency) new interleaved a priori information. Since the read access to the data memory RAM has already ended at this time, this new interleaved a priori information can be written to the data memory RAM directly without any buffer storage (that is to say “on-the-fly”) via the input 3 of the combined interleaver and deinterleaver IDL1, with α(i), i=19, . . . , 0. At this time, the drive addresses the write mode (r\overline{w}=0) via the signal connection 13. The deinterleaving mode il/\overline{dil}=0 is selected via the signal connection 14, and the deinterleaving process is likewise carried out “on-the-fly”.
4. The sliding window (that is to say the interval limits for the forward and backward recursion processes) is shifted through WS time steps to the right, and the process is started again from step 1. The steps 1-4 are continued until the block end is reached. If the block length K is not a multiple of the window size, the final computation step must be adapted appropriately.

The first turbo-iteration loop (see FIG. 10) is ended after carrying out the second computation run (corresponding to steps 1-4 as just described). The second turbo-iteration loop of the turbo-decoder algorithm starts with the third computation run of the turbo-decoder core TD_K. This computation run is likewise carried out in the four steps as described above, but now using α(i) for addressing rather than i directly.

The second and third computation runs as described above are then repeated until an iteration limit (for example a predetermined number of turbo-iteration loops) is reached. During the last computation run in the last turbo-iteration loop, the interleaved LLRs from the turbo-decoder core TD_K are read rather than the interleaved a priori information (which corresponds to Z_{I}). The first multiplexer MUX1 is switched via the control connection 12 for this purpose. The interleaved LLRs are deinterleaved for the last time in the combined interleaver and deinterleaver IDL1, and are read as deinterleaved reliability information (which corresponds to Λ2) via the data links 18, 20 and bus structure BU by the processor (which is not illustrated).

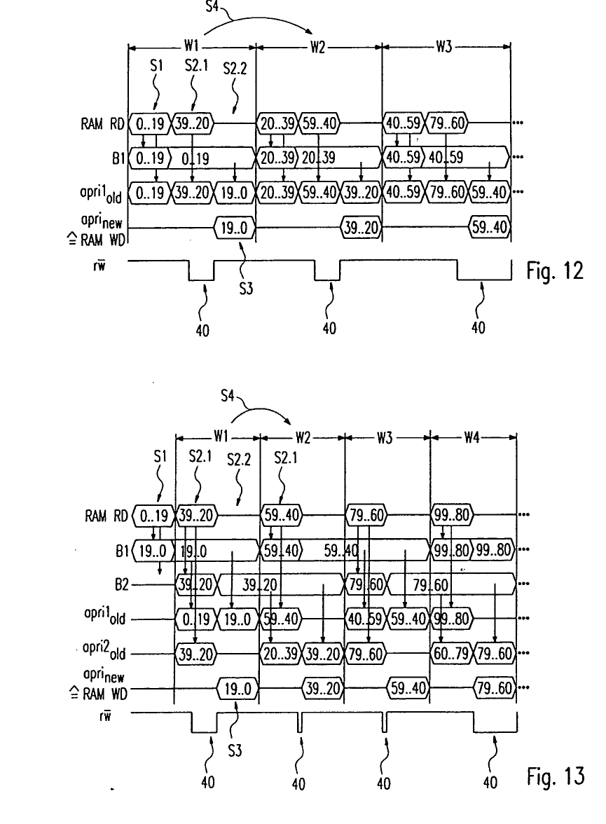

FIG. 12 illustrates the sliding window technique on the basis of an example. The illustration shows read accesses to the data memory RAM (RAM RD), the content of the buffer store B1 (B1), the supply of old a priori information via the input 30 to the turbo-decoder core TD_K (april_{old}), the output of new a priori information from the turbo-decoder core (TD_K (apri_{new}), and the read/write signal (r\overline{w}). The example relates to the situation where WS=20, X=40.

In the step S1, the forward metrics for the time steps 0-19 are read from the data memory RAM, are stored in B1 and are at the same time entered in the turbo-decoder core TD_K. In the step 2 (calculation of the backward metrics), the a priori information for the time steps 39-20 is first of all read from the data memory RAM, and is passed as data april_{old} to the turbo-decoder core TD_K (S2.1). The remaining a priori information for the time steps 19-0 is then read from the first buffer store B1, and is likewise passed as data april_{old} to the turbo-decoder core TD_K (S2.2). The new a priori information apri_{new} is calculated in the third step S3, at the same time as the step S2.2. Since the calculated a priori information apri_{new} is written to the data memory RAM at the same time, it must be switched to the read mode in advance, as is indicated by the reference symbol 40. The fourth step S4 comprises the window W1 being slid to the position W2, after which the steps S1-S4 are repeated.

Moving back to FIG. 11, one variant comprises the provision of a further buffer store B2 in parallel, in addition to the buffer store B1. The corresponding data links as well as a further multiplexer MUX2, which is required in addition, with the activation signal en_B2 are illustrated by dashed lines in FIG. 11. The a priori information which is available on the output side of the multiplexer MUX2 is denoted apri2_{old}, and is passed to the turbo-decoder core TD_K via a further input 31.

FIG. 13 shows an illustration, corresponding to FIG. 12, of the architecture with two buffer stores B1 and B2. The illustration in this case additionally shows the memory content of the second buffer store B2 (B2) and the supply of old a priori information apri2_{old} from the second buffer store B2 to the turbo-decoder core TD_K. The first buffer store B1 is filled first of all, in the step S1. The second buffer store B2 is filled with the a priori information for the time steps 39-30, in the step S2.1. The steps S2.2 and S3 are identical to the steps S2.2 and S3 illustrated in FIG. 12.

The transition to the next sliding window W2 in the step S4 results in the advantage that the a priori information for the time steps 20-39 is already available in the second buffer store B2. The step S1 is omitted. Only the steps S2.1, S2.2 and S3 need be carried out in the sliding window W2. The same applies to all the other sliding windows W3, W4, . . . , for the same reason.

The major advantages of the invention are summarized in the following text:

Both the interleaving and the deinterleaving of all the a priori information and LLRs can be carried out using only a single single-port data memory RAM “on-the-fly”.

Only the interleaving function α(i) (or, alternatively, the inverse deinterleaving function α⁻¹(i)) must be implemented, but not both functions: this saves virtually 50% of the memory area on the chip.

When the combined interleaver and deinterleaver IDL1 is implemented, no additional latency is required for the initialization of IDL1, since the turbo-decoder core TD_K can start its work even during the initialization of IDL1.

The implementation of the combined interleaver and deinterleaver IDL1 results in a further advantage in that the processor can always read the LLRs in non-interleaved form, independently of the last iteration step.

1. A Turbo-decoder, comprising a channel decoder and a circuit for interleaving and deinterleaving of a data stream, in which the circuit which carries out interleaving or deinterleaving of a data stream as a function of a selected mode, comprises
a data memory for temporary storage of the data in the data stream,
a first address generator which produces a sequence of sequential addresses for addressing the data memory
a second address generator which produces a sequence of addresses which represents the interleaving rule for addressing the data memory, and
a first logic means which causes the data memory to be addressed by the second address generator in the interleaving mode for a read process and in the deinterleaving mode for a write process, and to be addressed by the first address generator in the interleaving mode for a write process and in the deinterleaving mode for a read process, and in which the turbo-decoder is designed to carry out decoding based on the sliding window technique and, as available rewriteable memory area, comprises:
the common data memory in the circuit for interleaving and deinterleaving, and
a buffer store for temporary storage of interleaved or deinterleaved data which has been read from the data memory whose memory size is matched to the length of the sliding window.

2. The Turbo-decoder according to claim 1, wherein the logic means comprises:
an XOR gate whose inputs are connected to the write/read signal for the data memory and to a mode signal which indicates the mode, and
a multiplexer whose control input is connected to the output of the XOR gate, and whose multiplexer inputs are connected to the first and to the second address generator.

3. Turbo-decoder according to claim 1, wherein the data memory is a single port data memory.

4. The Turbo-decoder according to claim 1, wherein the available rewriteable memory area furthermore comprises a further buffer store for temporary storage of interleaved or deinterleaved data which has been read from the data memory, whose memory size is likewise matched to the length of the sliding window.

5. A Turbo-decoder, comprising a channel decoder and a circuit for interleaving and deinterleaving of a data stream, in which the circuit which carries out interleaving or deinterleaving of a data stream as a function of a selected mode, comprises
a data memory for temporary storage of the data in the data stream,
a first address generator which produces a sequence of sequential addresses for addressing the data memory,
a second address generator which produces a sequence of addresses, which represents the inverse interleaving rule for addressing the data memory, and
a second logic means which causes the data memory to be addressed by the second address generator in the interleaving mode for a write process and in the deinterleaving mode for a read process, and to be addressed by the first address generator in the interleaving mode for a read process and in the deinterleaving mode for a write process, and in which the turbo-decoder is designed to carry out decoding based on the sliding window technique and, as available rewriteable memory area, comprises:
the common data memory in the circuit for interleaving and deinterleaving, and
a buffer store for temporary storage of interleaved or deinterleaved data which has been read from the data memory whose memory size is matched to the length of the sliding window.

6. The Turbo-decoder according to claim 5, wherein the logic means comprises:
an XOR gate whose inputs are connected to the write/read signal for the data memory and to a mode signal which indicates the mode, and
a multiplexer whose control input is connected to the output of the XOR gate, and whose multiplexer inputs are connected to the first and to the second address generator.

7. The Turbo-decoder according to claim 5, wherein the data memory is a single port data memory.

8. The Turbo-decoder according to claim 5, wherein the available rewriteable memory area furthermore comprises a further buffer store for temporary storage of interleaved or deinterleaved data which has been read from the data memory, whose memory size is likewise matched to the length of the sliding window.
